(19) United States
(12) Patent Application Publication
(10) Pub. No.: US 2003/0066750 A1
(43) Pub. Date: Apr. 10, 2003

(54) Electrolytic combustion

(76) Inventor: Arthur Cheng-Hsin Wu, Foster City, CA (US)

Correspondence Address: ARTHUR C. WU, 969-G EDGEWATER BLVD #168, FOSTER CITY, CA, 94404, US

(21) Appl. No.: 09/971,173

(22) Filed: Oct. 4, 2001

(51) Int. Cl. C25C 7/00; C25B 9/00; C25D 17/00; C30B 7/12

(52) U.S. Cl. 204/242; 205/687

(57) ABSTRACT

An energy conversion system utilizes electrolytic combustion process to covert energy with given energy potential into energy with equal or higher energy potential. The energy conversion system utilizes energy from an energy storage device to electrolytically separate water into electrolytic products. The electrolytic products are fed into a combustion device with or without extra fuel to produce work for other applications or further to deliver work to a generator to generate electricity with equal or higher energy potential. If there is consistent supply of energy in the form of low energy potential, or if the air and extra fuel used in the combustion process contains sufficient combustible materials, the energy conversion system in the electrolytic combustion process becomes self-energy sufficient operation provided with continuous make up water supply.

### FEDERALLY SPONSORED RESEARCH

Not Applicable

### SEQUENCE LISTING OR PROGRAM

Not Applicable

### TECHNICAL FIELD

This invention related generally to energy conversion systems, and more particularly to energy conversion systems adapted to convert energy through electrolytic combustion process into work and energy.

### BACKGROUND OF THE INVENTION

Energy, particularly electricity, is one of the most crucial resources for industrial development. Beside the consumption of non-renewable natural energy resources, utilization of natural energy resources such as solar, wind, river flow, ocean wave, geo-thermal, or the combination of some of them is the active subject of energy research and technical development. Although the natural energy resources are abundant, the current technology still is limited to effectively convert energy from natural resources into our daily electricity usage in a mass scale. Consequently, there is an acute need to develop an energy conversion system to effectively utilize the availability of natural energy resources.

Further, there are lots of industrial facilities in which the exhaust waste heat is constantly generated and releases into ambient environment. Even the amount of energy is huge in total quantity, the exhaust waste heat is considered as relatively low in temperature and is deemed unrecoverable due to practical economic reason. It would be desirable to recover portion of waste heat into other usage form.

Still further, automobile burning petroleum products have been used extensively. With a new emphasis in establishing clean air standards and fuel consumption, there is an urgent need to improve fuel usage efficiency and generate less harmful emissions. It would be desirable to adapt electrolytic combustion process to improve fuel consumption and to generate less harmful emissions.

Special methods and apparatus have been proposed and constructed to deal with specific problems associated with specific usage with limited success, but no single overall electrolytic combustion methodology has been successful in dealing with wide variety of applications in an effective and efficient manner. None of the other methods and apparatus has successfully optimized the electrolytic combustion process. For this reason, there remains substantial room for improvement in the field.

### BRIEF DESCRIPTION OF THE INVENTION

Accordingly, it is the object of the present invention to provide an energy conversion system, which is capable of efficiently converting energy from natural energy resources such as solar, wind, river flow, ocean wave, geo-thermal, and the like, especially the energy potential could be low even through the total energy quantity is huge, into a ready to use energy form, particularly electricity.

It is another object of the present invention to provide an energy conversion system, while adapting to a power generation facility, the energy conversion system can store electric energy during low load period, and supply the stored energy during high load period.

It is a further object of the present invention to provide an energy conversion system, while adapting to an industrial facility, the energy conversion system is capable of storing energy from industrial exhaust waste heat, and supply the stored energy in an usable form when there is a need.

It is another object of the present invention to provided an energy conversion system, while adapting to biological fermentation gas, the energy conversion system is capable of converting biological by-products into an energy storage form, and supply the stored energy in a form of electricity when it is needed.

It is still another object of the present invention to utilize an energy conversion system to break up chemical bonds of the combustible hazard chemicals, such as aromatic hazard chemicals, halogen chemicals, or aromatic-halogen chemicals, while in the process of breaking up combustible hazard chemicals, the energy conversion system still can perform energy storage for future or other application.

It is yet another object of the present invention to adapt an energy conversion system into a vehicle, in which it has an internal combustion engine equipped with igniters, while the energy conversion system is in the process to convert extra stored energy into vehicle's mechanical power output, it improves vehicle's fuel efficiency and exhaust emission.

It is an additional object of the present invention to adapt an energy conversion system into a vehicle, in which the vehicle has an internal combustion engine without igniter, while the energy conversion system is in the process to convert a stored energy into mechanical power output, it improves vehicle's fuel efficiency and also improves exhaust emission.

Still another object of the present invention is to provide energy from natural energy resource to a vehicle's internal combustion engine equipped with or without igniter, so the energy conversion system can convert received energy from natural resources into the power output of the internal combustion engine.

Briefly, a preferred embodiment of the present invention is an energy conversion system, which is capable of converting stored energy with low energy potential through an electrolytic combustion process into mechanical output, and is capable of producing work and generating electrical energy with the same or higher energy potential. The energy conversion system utilizes stored energy from an energy storage device to electrolytically separate water in an electrolytic cell into fuel and oxidizer. The fuel can include hydrogen and ionized electrolytic products. The fuel is supplied into a combustion device to produce power output, where the power output either can produce work for other applications or deliver to a generator to generate electricity. When water is electrolyzed by energy from an energy storage device into hydrogen fuel and oxygen oxidizer. The hydrogen fuel is burned in a combustion device and converts chemical energy into heat and power output, and the final combustion product which primary is water can be in the form of gas phase, liquid phase, or the combination of both. The water, in the electrolytic combustion process initially is electrolytically converted into fuel and oxidizer, and the fuel is further chemically converted back to water, is considered as an energy conversion media in the energy conversion system. The energy conversion system in the electrolytic combustion process utilizes energy from the energy storage device to initiate the operation of dissociating and later reforming water, and overcomes the energy loss in both electrolysis and combustion processes. If there is a consistent supply of energy in the form of low energy potential, or if the air used in the combustion process contains sufficient quantity of combustible materials, the energy conversion system in the electrolytic combustion process can become self-sustainable operation provided with continuous make up water supply.

An advantage of the present invention is that the energy conversion system utilizes the electrolytic combustion process which is able to convert low energy potential such as direct current low voltage into high energy potential such as alternating current high voltage, and to make the energy storage in the form of low energy potential become practically attractive feature to store all unused energy.

Another advantage of the present invention is that the energy conversion system consumes and generates water, and also can be utilized to do wastewater treatment while performing energy conversion process.

A further advantage of the present invention is that the use of wide band frequency voltages for electrolysis process can result in an improved quantity of products generated from an electrolytic cell without causing excess amount of heat to raise the liquid temperature of the electrolytic cell.

A still further advantage of the present invention is that the use of a suitable electric field gradient in an electrolytic cell can efficiently generate electrolytic products, and can avoid the need to utilize extra storage apparatus for storing electrolytic products.

Another further advantage of the present invention is that the energy conversion is able to generate hydrogen and ionized electrolytic products, and mixes with hydrocarbon fuel to perform chemically reacting in the combustion process, wherein ionized electrolytic products are able to attach to the hydrocarbon fuel to improve the chemical reacting process during combustion.

Yet another advantage of the present invention is that the energy conversion system can be adapted to utilize hydrogen, oxygen and ozone generated from water in the electrolysis process to feed into the combustion process, which also receives combustible hazard chemicals mixed in the air, can result in an improved ability to decompose combustible hazard chemicals in the combustion process, while performing energy conversion process the energy conversion also can destruct the combustible hazard chemicals in an efficient manner.

Still another advantage of the present invention is that the energy conversion system can be further adapted to utilize the combination of hydrogen, oxygen, ozone and chlorine-hypochlorite generated from water and electrolytes in the electrolysis process to feed into the combustion process, which also receives combustible hazard chemicals mixed in the air, can result in an improved ability to decompose combustible hazard chemicals in the combustion process in an effective manner, while performing energy conversion process.

A further advantage of the present invention is that the energy conversion system can be adapted to convert salt water into fresh water and salt, while the energy conversion system becomes self-sustainable operation by continuously receiving natural energy resource.

These and other objects and advantages of the present invention will become clear to those skilled in the art upon review of the following specification, the accompanying drawings and the appended claims.

### BRIEF DESCRIPTION OF THE DRAWINGS

FIG. 1 is a schematic diagram of energy conversion system;

FIG. 2 is a graphical view to show one potential relationship between normalized voltage magnitude verse frequency ranges;

FIG. 3 is a graphical view to show one potential relationship between normalized voltage magnitude verse time sequences.

### DETAIL DESCRIPTION OF THE PREFERRED EMBODIMENTS

The present invention provides for an energy conversion system, comprising: a wide band frequency converter to convert an energy potential into an oscillatory voltage, wherein said oscillatory voltage varies with respect to the wide band frequency of said wide band frequency converter, an electrolytic cell to produce an electrolytic product, wherein said electrolytic cell receives said oscillatory voltage for generating said electrolytic product, wherein said oscillatory voltage reduces the electrostatic effect of the cathode and the anode of said electrolytic cell on said electrolytic product. Preferably the energy conversion system further comprising a combustion device to consume said electrolytic product for producing work and heat. Preferably the energy conversion system further comprising an energy storage device to provide said energy potential for said wide band frequency converter. Preferably the energy conversion system further comprising a generator to convert said work into energy with equal or higher said energy potential. Preferably the energy conversion system further comprising a charger to deliver portion of energy from said generator into said energy storage device. Preferably the energy conversion system, wherein said oscillatory voltage decreases with respect to increasing of said wide band frequency. Preferably the energy conversion system, wherein said oscillatory voltage periodically reverses the polarity of said cathode and said anode for reducing scale build up said cathode and said anode. Preferably the energy conversion system, wherein said wide band frequency is frequency modulated. Preferably the energy conversion system, wherein said wide band frequency is magnitude modulated. Preferably the energy conversion system, wherein said wide band frequency is pulse width modulated. Preferably the energy conversion system, wherein said oscillatory voltage is a series on and off voltage. Preferably the energy conversion system, wherein said wide band frequency has a frequency range, said frequency range is at least 1 KHz and no more than 10 MHz. Preferably the energy conversion system, wherein said wide band frequency has a signal cycle range, said signal cycle range is no more than 1000000 signals.

The present invention is an energy conversion system, comprising: an energy storage device to provide energy potential, a wide band frequency converter to convert said energy potential into an oscillatory voltage, wherein said oscillatory voltage varies with respect to the wide band frequency of said wide band frequency converter, an electrolytic cell to produce an electrolytic product, wherein said electrolytic cell receives said oscillatory voltage for generating said electrolytic product, wherein said oscillatory voltage reduces the electrostatic effect of the cathode and the anode of said electrolytic cell on said electrolytic product, a combustion device to consume said electrolytic product for producing work and heat, a generator to convert said work into energy with equal or higher said energy potential, a charger to deliver portion of energy from said generator into said energy storage device.

The present invention provides a method of providing energy, comprising: converting an energy potential into an oscillatory voltage with a wide band frequency converter, wherein said oscillatory voltage varies with respect to the wide band frequency of said wide band frequency converter, generating a combustible product with an electrolytic cell, wherein said electrolytic cell receives said oscillatory voltage from said wide band frequency converter, and heating a mixture of said combustible product with a combustion device to produce energy. Preferably a method of providing energy, wherein said oscillatory voltage decreases with respect to increasing of said wide band frequency. Preferably a method of providing energy, wherein said oscillatory voltage is frequency modulated. Preferably a method of providing energy, wherein said oscillatory voltage is magnitude modulated. Preferably a method of providing energy, wherein said oscillatory voltage is pulse width modulated. Preferably a method of providing energy, wherein said wide band frequency converter has a frequency range of at least 1 KHz and no more than 10 MHz. Preferably a method of providing energy, wherein said oscillatory voltage periodically reverses the polarity of the cathode and the anode of said electrolytic cell.

The present invention provides a method of providing energy, comprising: converting an energy potential into an oscillatory voltage with a wide band frequency converter, wherein said oscillatory voltage varies with respect to the wide band frequency of said wide band frequency converter, generating a combustible product with an electrolytic cell, wherein said electrolytic cell receives said oscillatory voltage from said wide band frequency converter, heating a mixture of said combustible product with a combustible device to produce energy, wherein said oscillatory voltage periodically reverses the polarity of the cathode and the anode of said electrolytic cell.

The present invention also provides an energy conversion system, comprising: an electrolytic cell to generate an ionized electrolytic product and a non-ionized electrolytic product, a combustion device to chemically react said ionized electrolytic product and said non-ionized electrolytic product. Preferably the energy conversion system, wherein said ionized electrolytic product is ozone. Preferably the energy conversion system, wherein said ionized electrolytic product is chlorine-hypochlorite. Preferably the energy conversion system, wherein said ionized electrolytic product and said non-ionized electrolytic product chemically react with fuel in said combustion device. Preferably the energy conversion system, wherein said fuel is a hydrocarbon chemical. Preferably the energy conversion system further comprising a wide band frequency converter to provide an energy potential into said electrolytic cell. Preferably the energy conversion system, wherein said energy potential is an oscillatory voltage. Preferably the energy conversion system, wherein said oscillatory voltage varies with respect to the wide band frequency. Preferably the energy conversion system, wherein said oscillatory voltage periodically reverses the polarity of the cathode and the anode of said electrolytic cell.

The present invention also is an energy conversion system, comprising: a wide band frequency converter to provide an energy potential, an electrolytic cell to receive said energy potential and to generate an ionized electrolytic product and a non-ionized electrolytic product, a combustion device to chemically react said ionized electrolytic product and said non-ionized electrolytic product.

The present invention also provides a method of providing energy, comprising: generating an ionized electrolytic product and a non-ionized electrolytic product with an electrolytic cell; and heating a mixture of said ionized electrolytic product and said non-ionized electrolytic product to produce energy. Preferably a method of providing energy further comprising: converting an energy potential to an oscillatory voltage with a wide band frequency converter into said electrolytic cell. Preferably a method of providing energy, wherein said ionized electrolytic product is ozone. Preferably a method of providing energy, wherein said ionized electrolytic product is chlorinehypochlorite. Preferably a method of providing energy, wherein said oscillatory voltage has a frequency range of at least 1 KHz and no more than 10 MHz.

The present invention also provides a method of providing energy, comprising: converting an energy potential to an oscillatory voltage with a wide band frequency converter, generating an ionized electrolytic product and a non-ionized electrolytic product with an electrolytic cell, wherein said electrolytic cell receives said oscillatory voltage, heating a mixture of said ionized electrolytic product and said non-ionized electrolytic product to produce energy.

The present invention also is an energy conversion system, comprising: an energy storage device to store energy and to provide energy in a form of an energy potential, a wide band frequency converter to convert said energy potential into an oscillatory voltage, wherein said oscillatory voltage varies with respect to the wide band frequency of said wide band frequency converter, an electrolytic cell having at least one set of the cathode and the anode, wherein said electrolytic cell generates an ionized electrolytic product and a non-ionized electrolytic product, and a combustion device to chemically react said ionized electrolytic and said non-ionized electrolytic product to produce energy. Preferably the energy conversion system, wherein said ionized electrolytic product is ozone. Preferably the energy conversion system, wherein said ionized electrolytic product is chlorine-hypochlorite. Preferably the energy conversion system, wherein said oscillatory voltage has a frequency range, wherein said frequency range is no more than 10 MHz.

The present invention further is an energy conversion system, comprising: an energy storage device to store energy and to provide energy in a form of an energy potential, a wide band frequency converter to convert said energy potential into an oscillatory voltage, wherein said oscillatory voltage varies with respect to the wide band frequency of said wide band frequency converter, an electrolytic cell having at least one set of the cathode and the anode, wherein said electrolytic cell generates ionized electrolytic product and a non-ionized electrolytic product, a combustion device to chemically react said ionized electrolytic product and said non-ionized electrolytic product with fuel to produce energy.

The present invention also provides an energy conversion system, comprising: an energy storage device to store energy and to provide energy in a form of an energy potential, a wide band frequency converter to convert said energy potential into an oscillatory voltage, an electrolytic cell to produce an electrolytic product, wherein said electrolytic cell receives said oscillatory voltage for generating said electrolytic product, wherein said oscillatory voltage reduces the electrostatic effect of the cathode and the anode of said electrolytic cell on said electrolytic product, an internal combustion engine equipped with an igniter to burn mixture of said electrolytic product, air and fuel to generate work for a vehicle, wherein the ratio of the number of molecules of said electrolytic product to the number of molecules of fuel is no more than 25%. Preferably the energy conversion system, wherein said oscillatory voltage has a frequency range, wherein said frequency range is no more than 10 MHz.

The present invention provides for an energy conversion system, comprising: a switch device to select an operation mode of said energy conversion system, wherein said operation mode has a hydrogen mode and a gasoline mode, an energy storage device to store energy and to provide energy in a form of an energy potential, a wide band frequency converter to convert said energy potential into an oscillatory voltage, an electrolytic cell to produce an electrolytic product, wherein said electrolytic cell receives said oscillatory voltage for generating said electrolytic product, wherein said oscillatory voltage reduces the electrostatic effect of the cathode and the anode of said electrolytic cell on said electrolytic product, an internal combustion engine equipped with an igniter to generate work, wherein said internal combustion engine bums said electrolytic product mixed with air during said hydrogen mode, and wherein said internal combustion engine burns gaseous gasoline mixed with air during said gasoline mode. Preferably the energy conversion system, wherein said oscillatory voltage has a frequency range, said frequency range is no more than 10 MHz.

The present invention provides for an energy conversion system, comprising: an energy storage device to store energy and to provide energy in a form of an energy potential, a wide band frequency converter to convert said energy potential into an oscillatory voltage, an electrolytic cell to produce electrolytic product, wherein said electrolytic cell receives said oscillatory voltage for generating said electrolytic product, wherein said oscillatory voltage reduces the electrostatic effect of the cathode and the anode of said electrolytic cell on said electrolytic product, an internal combustion engine bums a mixture of said electrolytic product, air, and fuel by increasing the pressure of said mixture and causing said mixture to self-ignite, wherein the ratio of the number of molecules of said electrolytic product to the number of molecules of said fuel is no more than 20%. Preferably the energy conversion system, wherein said oscillatory voltage has a frequency range, said frequency range is no more than 10 MHz.

The present invention is an energy conversion system, which is adapted to convert a stored energy into a usable form. The energy conversion system utilizes the electrolytic combustion process, which is adapted to be used in variety of industrial and commercial applications.

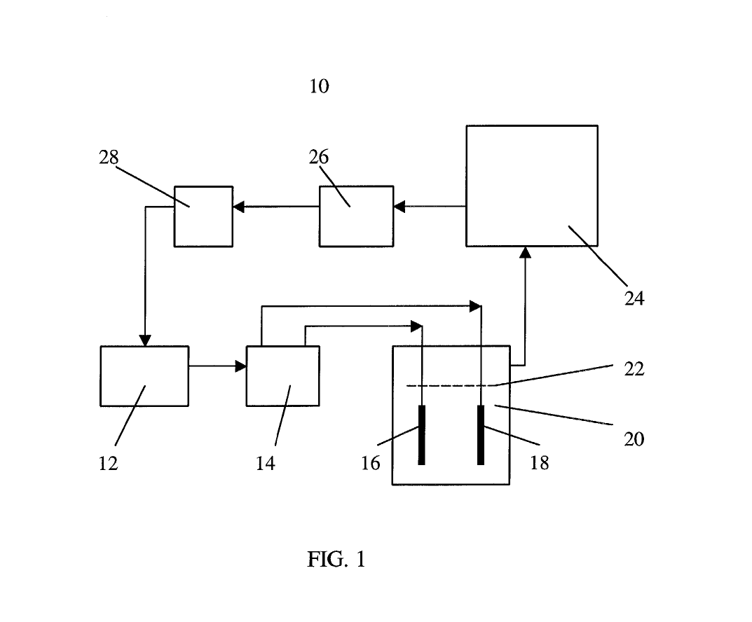

A preferred embodiment of the energy conversion system is illustrated in a schematic diagram in FIG. 1, and is referred to by the general reference 10. In this illustration it may be seen that the energy conversion system 10 is adapted to receive energy from an energy storage device 12. The energy storage device 12 can be a battery cell, an energy cell, or a device which can chemically or electrochemically store energy.

The energy conversion system 10 further illustrates a wide band frequency converter 14, which is electrically connected to the output of the energy storage device 12, and the outputs from the wide band frequency converter 14, including positive voltage and negative voltage, are electrically connected to a positive charged electrode 16 and a negative charged electrode 18 of an electrolytic cell 20 respectively. The electrolytic cell 20 contains water and electrolytes, and maintains the water level such that the positive charged electrode 16 and the negative charged electrode 18 are submerged in the water. Near and beneath the water surface is a perforated plate 22 to allow generated gas passing through and also is used to reduce possible wave motion on the water surface. When water is consumed and the water level is lower than the perforated plate 22, make up water is supplied to refill the water above the perforated plate 22. The electrolytes can be potassium hydroxide, calcium hydroxide, or ionized particles contained in the tap water.

In the electrolysis process the mass of substance liberated at an anode or cathode is in direct relationship with electrochemical equivalent of the substance times the quantity of electricity passed. Therefore the rate of electrolytic decomposition of an electrolyte is dependent on current and is not directly related to voltage magnitude provided that the voltage magnitude exceeds the minimum necessary for the activation of electrolysis. For most electrolytes, the minimum voltage is very low.

Since the electric current is the main determined factor to generate quantity of liberated products, the contact surface condition between electrolytes and electrode plate becomes one of the dominant factors to improve the generation of liberated products. When electrolytes reach one of the electrode plates by either receiving or giving away electrons to form the gas phase products, for example, hydrogen and oxygen are generated at the cathode and the anode. The gas phase molecules form gas bubbles and are still stayed on the electrode plate due to the electrostatic and other effects. The gas bubbles are growing by combining with other nearby gas phase molecules until the size of bubble is large enough such that the buoyancy force on the bubble is greater than the electrostatic effect from electrode plate, then the gas bubble is raised up to the water surface and is temporarily stored at the upper region of the electrolytic cell 20.

If gas bubbles occupy the surface of electrode plates, whether the electrode plate is anode or cathode, this can significantly reduce the effectiveness of the electrode plate to perform electrolysis reaction. The introduced electricity in the electrode plate is blocked by the gas bubbles and cannot perform proper electrolysis reaction, and consequently electricity in the electrode plate turns into heat and gradually raises the liquid temperature.

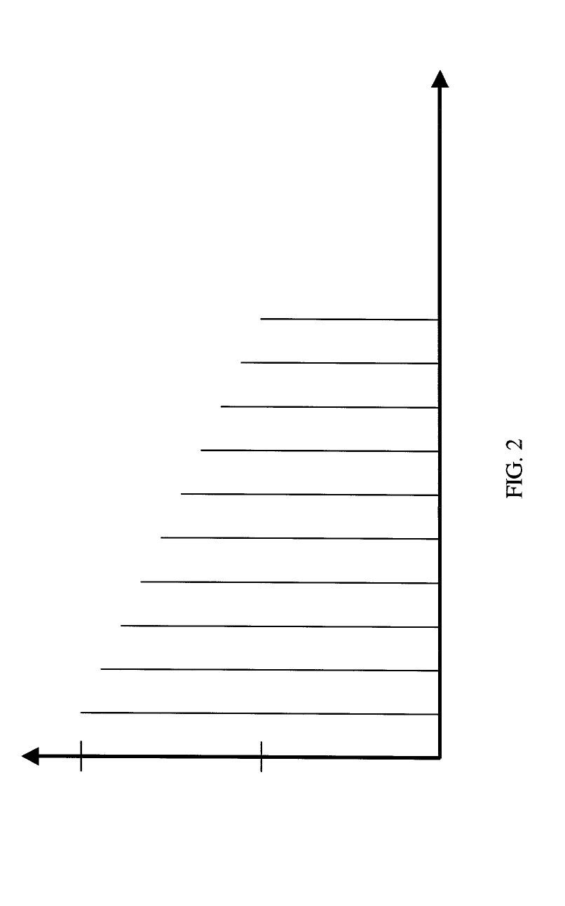

The wide band frequency converter 14 converts an energy potential such as direct current voltage from energy storage device 12 into an oscillatory voltage. This can be accomplished by utilizing a function generator with an appropriated frequency range plus a signal modulator to amplify and modulate the wave signals. The wave signals can be functional signals or pulse signals. For illustration purpose, FIG. 2 shows one of the possible wave formations as a pulse wave with a wide band frequency formation. The horizontal axis represents frequency range and the vertical axis represents normalized voltage magnitude. The total frequency formation represents one wide band frequency formation cycle. Referring to FIG. 2, near the lowest band of frequency point is set to have relative amplitude as close to 1 and near highest band of frequency point is set to have relative amplitude as close to 0.5. By filtering off the negative portion of pulse signals, the wide band frequency signals become on and off signals with variable voltage magnitude. The normalized voltage magnitude decreases as the frequency band increasing. The normalized voltage magnitude-decreasing rate can be linear, curve, or other shape respect to frequency increasing. Other potential wave formation can be applied such as a shifted Fourier transform formation. Applying a filtered wide band frequency formation with predetermined positive and negative voltages to the respective electrode plates can introduce a series of voltages to perform electrolysis reaction in the electrolytic cell 20, and can have significant benefits to generate electrolytic products.

Referring to FIG. 1, the wide band frequency converter 14 illustrated in the energy conversion system 10 can introduce wide band frequency voltages on the positive charged electrode 16 and the negative charged electrode 18. One of the major advantages of the wide band frequency voltages is that the electrode plates are induced by a vibration mode. The vibration motion can quickly remove gas bubbles, which are deposited on the electrode plates. The introduction of a vibration motion on the electrode plates can avoid the need to utilize air to perform gas bubbles blowing up from the bottom portion of the electrolytic cell 20. The operation of gas bubbles blowing up inevitably introduces turbulent flow in the liquid of the electrolytic cell 20 and reduces the performance on the electrode plates. The introduction of a vibration motion on the electrode plates also can avoid the need to circulate water on the boundary of the electrolytic cell 20 for reducing the liquid temperature.

Although the voltage introduced in electrolysis does not directly contribute the benefit to the electrolysis process, the electrode field strength, more specifically, the electric field gradient with respect to the direct distance between an anode and cathode, does have direct contribution to the electrolysis process. When ionized molecules, including electrolytes and ionized water molecules, are in the presence of strong electrode field strength, the ionized molecules would rotate and adjust their each individual molecular orientation to the right position along the line of electrode field strength, and migrate into one of the electrode plates by the induced force caused by the electrode field strength. When ionized molecules are in the presence of relatively weak electrode field strength, for example, the electrode plates are far apart so the electric field gradient in the electrolyte solution is relatively weak, the ionized molecules would have near random orientation of their individual molecule. So when one individual ionized molecule reaches the electrode plate, the individual ionized molecule may not be ready for the electrolysis reaction due to its orientation need to be readjusted. By placing the positive charged electrode 16 and the negative charged electrode 18 of the electrolytic cell 20 in a close space to increase the electrode field strength can have the advantage of quick electrolysis reaction to generate quantity of products. The geometry shape of positive charged electrode 16 and negative charged electrode 18 can be flat plates, or two concentric circular cylinder shapes, or other geometry shapes.

When filtered wide band frequency voltages are introduced in the electrolytic cell 20, the electrode plates experience an oscillatory voltage, or a series of on and off voltage, from the wide band frequency converter 14. The series of on and off voltage generates a vibration motion on electrode plates. During the voltage on period, the electrode field strength is actively inducing a force on the respective ionized molecules, that is, a positive charged molecule is pulling toward the negative charged electrode 18 and a negative charged electrolyte is moving toward to the positive charged electrode 16. The electrolysis reaction under the influence of suitable scale electrode field strength can increase the forming gas bubbles on the electrode plates. During the voltage off period, the electrode field strength is terminated and the electrostatic effect between an electrode plate and gas bubbles is significantly reduced. The continuous vibration motion on the electrode plates can assist the release of gas bubbles from the electrode plates. Furthermore, the scale build up on the surfaces of both electrode plates can also be reduced.

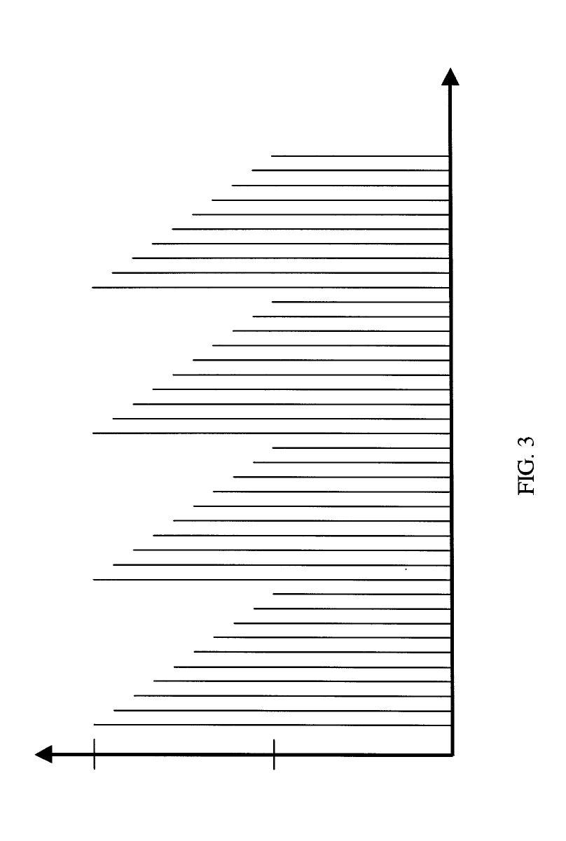

The combination of utilizing wide band frequency voltages and electrode field strength in the electrolytic cell 20 can efficiently improve the generation of electrolytic products in the electrolysis reaction. During the voltage on period, the electrode field strength can induce an attracting force to pull opposite charged ionized molecules to the respective electrode plates, that is, an anode and cathode, to exchange electrons. During the voltage off period, the electrode field strength is temporally turned off; this can give ionized molecules time to adjust each individual orientation and to prepare electrons exchange. When the voltage is on again, the ionized molecules are ready to either give away or receive electrons. As illustrated in FIG. 2, when frequency signal is near the low boundary of frequency band, the magnitude of normalized voltage is relatively high. When frequency signal is near the upper boundary of frequency band, the magnitude of normalized voltage is relatively low. Because the forming of hydrogen, oxygen and other electrolytic products require different levels of energy, the variable magnitude of voltages introduced on the electrode plates can compensate the needs to form each individual electrolytic product. The changing voltage magnitude with respect to frequency also alter the magnitude of electrode field strength in the electrolytic cell 20 correspondingly. Consequently, the ionized molecules located between electrode plates receive variable magnitude of field force, this allows ionized molecules moving along the line of electrode field strength and adjusting each individual orientation for electrons exchange. The direct benefit is to have better yield of electrolytic products. As illustrated in FIG. 3, a series of on and off voltage of wide band frequency formation is shown in time sequence and normalized voltage magnitude. The horizontal axis represents time sequence and the vertical axis represents normalized voltage magnitude. Each frequency formation cycle is shown to have 10 ideal pulse signals. Therefore, by varying frequency range and voltage range, the wide band frequency converter 14 can convert direct current voltage into a series of variable magnitude voltages with variable frequency sequence to efficiently generate electrolytic products in the electrolytic cell 20. In each wide band frequency formation cycle, hydrogen, oxygen, other electrolytic products and ionized electrolytic products, can be generated in an efficient manner. In macroscopic point of view, the electrolytic products are generated almost immediately as the wide band variable frequency voltages are applied.

The range of wide band frequency applied in the electrolytic cell 20 can be in the range of 1 KHz to 10 MHz, more preferably can be in the range of 1 KHz to 5 MHz. And further desirable range of wide band frequency can be in the range of 1 KHz to 3 MHz. Each wide band frequency formation cycle can have 1000000 signals or less, and preferred range can have 500000 signals or less. The wide band frequency can be amplitude modulated, frequency modulated, or pulse width modulated. The electrode field strength applied in the electrolytic cell 20 can be in the range of 3 volt/cm or higher, more preferably can be in the range of 4 volt/cm or higher.

One of the advantages of utilizing the combination of wide band frequency voltages and electrode field strength is that the energy conversion system 10 of the invention can avoid the need to provide an extra storage device to store gas phase electrolytic product such as hydrogen or other electrolytic products. Generally the storage device needs to be pressurized in order to improve the storage performance. The operation of pressurizing electrolytic products into a storage device requires extra work and cost, and may not be desirable in some applications. With the proper combination of wide band frequency voltages and electrode field strength, the electrolytic cell 20 can generate almost instant quantity of hydrogen when the current is supplied, and the generated hydrogen is temporally occupied the upper portion space of electrolytic cell 20. If there is a need to increase the quantity of hydrogen, plurality sets of electrode plates or plurality sets of electrolytic cell 20 can provide more electrolysis reaction area.

As illustrated in the energy conversion system 10 of FIG. 1, the gas output of the electrolytic cell 20 is connected to a combustion device 24. The gas products generated in the electrolytic cell 20, which may include hydrogen fuel, oxygen oxidizer, and water vapor, are fed into a combustion device 24. The combustion device 24 mixes the gas products with air in the burning process to consume hydrogen fuel and generates high temperature of combustion products. The output of combustion products is producing work for other usages or is feeding into a generator 26 to generate electricity. In practical example, the combustion device 24 and the generator 26 can be the combination of a gas burner with a gas turbine plus an electric generator, or the combination of a gas burner with a steam boiler plus a steam turbine and an electric generator, or an internal combustion engine plus an electric generator, or other similar apparatus combinations. If the output of the generator 26 has extra amount of electricity, which does not have immediate usage, the extra electricity is delivered through a charger 28 to store energy back to the energy storage device 12.

The electrolytic cell 20 can generate the mixture of hydrogen and oxygen. In some applications, it would be desirable to collect the hydrogen fuel and oxygen oxidizer separately in the electrolytic cell 20. This can be accomplished by adding a divider (not shown) on the space between anode and cathode. Therefore when hydrogen and oxygen are generated on the electrode plates, the hydrogen is flowing up to occupy its restricted space, and the oxygen is also flowing to its separate designated space. The hydrogen is the primary fuel collected from the electrolysis process for the further combustion process, and the oxygen can be stored for other applications or be discarded if there is no further usage.

For some applications, there is a need to collect electrolytic products all together. Further, it is desirable to reduce, and even remove, the scale build up on the electrode plates. The wide band frequency converter 14 can periodically reverse the polarity of the oscillatory voltage, that is, the anode is changed into cathode, and the cathode is changed into anode. For example, initially the positive oscillatory voltage is connected to the positive charge electrode 16 and the negative oscillatory voltage is connected to negative charge electrode 18. After a given period such as ten minutes, the positive oscillatory voltage is connected to the negative charge electrode 18 and the negative oscillatory voltage is connected to the positive charge electrode 16. For another given period of time, the positive oscillatory voltage is connected back to the positive charge electrode 16 and the negative oscillatory voltage is connected back to the negative charge electrode 18. This polarity reversing may cause disturbance in the electrolysis reaction momentarily. However, any scale build up on cathode or anode is released by reversing polarity, and scale may further dissolve back into liquid.

The hydrogen fuel is very light in molecular weight, high volatility, and its burning velocity is extremely fast. It would be desirable to make hydrogen burning more controllable in the combustion device 24 whether the combustion device 24 is a gas burner or an internal combustion engine. For the case of burning hydrogen fuel in a premixed gas burner, by adjusting proper fuel to air ratio, premixed fuel mixture flow velocity, and the rate of ambient air entrenchment into the flame can retain the stability of hydrogen flame and sustain hydrogen fuel burning on the nozzle of a gas burner.

For the case of burning hydrogen fuel in a conventional internal combustion engine equipped with igniters, the hydrogen fuel has much lighter molecular weight compared with a regular gasoline fuel such as octane. The molecular weight ratio of octane verse hydrogen is over 50. The original design of a conventional internal combustion engine equipped with igniters is for gasoline, propane, and nature gas burning. One mole of octane gasoline requires roughly at least 12.5 moles of air for octane burning at stoichiometric condition. In general, an internal combustion engine equipped with igniters is designed for fuel lean burning and has compressed ratio about 9 to 12, and some models can even go higher. Since one mole of hydrogen gas only requires about 0.5 mole of air for hydrogen burning at stoichiometric condition, consequently, more moles of hydrogen gas are needed to replace one mole of octane to generate equivalent heat. Based upon adiabatic combustion condition, it needs about 21 moles of hydrogen gas to generate equivalent heat of one mole octane gas burning at stoichiometric condition. For a given internal combustion engine, the size of combustion chamber is a fixed parameter and cannot be enlarged. Therefore, considerable less amount of hydrogen fuel can be placed in the combustion chamber to totally replace octane fuel. The direct result is that the internal combustion engine equipped with igniters shows lower engine temperature when solely applying hydrogen as fuel.

The energy conversion system 10 of the present invention can be adapted to take advantage of its ability to convert energy in the form of low energy potential into a high energy potential from various resources. For examples in the fields of renewable energy, the solar panel is utilized to receive solar energy through the photovoltaic process to convert visible light or electromagnetic radiation into low voltage energy and is stored in the energy storage device 12. The windmill with an electric generator can convert wind flow kinetic energy into low voltage electricity and is stored in the energy storage device 12. The flow and wave motions of river flow and ocean wave also can be converted their respective kinetic energy into a form of low voltage energy and is stored in the energy storage device 12. The geo-thermal energy can be converted through a heat pump and an electric generator to transform heat energy with temperature difference into a form of low voltage energy and further is stored in the energy storage device 12. For industrial waste heat recovery applications, the heat energy in the form of temperature difference can be converted into a form of low voltage potential, for example, a heat pump with an electric generator, and is stored in the energy storage device 12.

The energy stored in the energy storage device 12 is stable and can be stored for a long period of time with limited loss. The energy stored in the energy storage device 12 is ready to be utilized when there is a need, through the electrolytic combustion process to convert energy from low energy potential into a form of energy with desirable energy potential.

The energy conversion system 10 of the present invention can be adapted to take advantage of its ability to consume extra combustible materials in the combustion process to improve industrial exhaust. Some industrial facilities generate industrial exhaust, which can contain carbon monoxide, solid carbon particles, and other light hydrocarbon materials. If the industrial exhaust contains low amount of combustible materials, but the concentration is not low enough to meet local emission requirements, the combustion device 24 can burn the mixture of hydrogen, oxygen, air and the industrial exhaust together. Furthermore, the mechanical output from combustion device 24 can produce work for the generator 26 and generate electricity for other applications or through the charger 28 to store energy into the energy storage device 12.

Therefore the energy conversion system 10 can be adapted to improve industrial exhaust emissions while storing energy from the combustion burning of industrial exhaust to sustain the operation, and even may export energy generated in the combustion process. The energy conversion system 10 also can be adapted to improve biological fermentation exhaust while utilizing fermentation exhaust as the fuel to sustain the operation of improving biological fermentation exhaust. The biological fermentation exhaust can be the exhaust output from fertilizer compost, sludge fermentation, or any facility utilizes aerobic and anaerobic fermentation process.

The energy conversion system 10 can be adapted to take advantage of its ability to generate ionized electrolytic products such as ozone and other ionized radicals in the electrolysis process and further can be implemented in the combustion process to improve destruction of the combustible materials. Combustible materials can have hydrocarbon materials and combustible hazard materials. By placing the anode and cathode close enough in the electrolytic cell 20 to increase the electrode field strength; in addition of forming non-ionized electrolytic product, ionized electrolytic product is generated in the electrolysis reaction. When the electrode field strength is high enough, some oxygen molecules are further activated before leaving the electrode plate and are converted into an ozone state or ionized oxygen state. For example, if the electrode field strength is 15 volt/cm or higher, that is, for the voltage difference between anode and cathode is 12 volts, and the distance between anode and cathode is around 0.8 centimeter or less, some portion of oxygen molecules are electrically activated to form ozone product.

The combustible hazard chemicals can have hydrocarbon chemicals, aromatic chemicals, halogen chemicals, and aromatic-halogen chemicals, which generally prefer burning at high temperature and make the destruction of these chemicals very difficult to control. The combustible hazard chemicals can include PCBs such as Polychlorinated Biphenyls and related chemicals, CFC such as Dichlorodifluoromethane and related chemicals, Dioxin such as 2,3,7,8-tetrachlorodibenzo-p-dioxin and related compounds, Agent Orange, and other aromatic based chemicals.

Because hydrogen itself has no polarity property, when the combustion chamber is received hydrogen, oxygen, ionized electrolytic products, air and large size molecules such as the combustible hazard chemicals, the ionized electrolytic products such as ozone, are attaching to the combustible hazard chemicals and other large size molecules due to electric attraction force. During the combustion process, the hydrogen quickly reacts with oxygen to raise the chamber temperature. The heat and the attached ozone can improve the dissociation of the combustible hazard chemicals. Once the inter-chemical bonds of combustible hazard chemicals are broken, the oxygen and ozone molecules are ready for further chemical oxidization process, and form final combustion products.

The energy conversion system 10 of the present invention can be further adapted to take advantage of its ability to generate ionized electrolytic products such as ozone, chlorine-hypochlorite in the electrolysis process and to improve the effective destruction of the combustible hazard chemicals in the combustion process. By adding sodium chloride or calcium chloride in the water as electrolytes, the electrolysis process under suitable electric field strength can generate hydrogen, oxygen, ozone, and chlorine-hypochlorite in the gas form. When the combustion chamber is received mixture of hydrogen, oxygen, ozone, chlorine-hypochlorite, air and the combustible hazard chemicals, the chlorine-hypochlorite can effectively attach on the combustible hazard chemicals due to the electric attraction force. During the combustion process, the temperature raised by hydrogen burning can provide activated chain reaction to start dissociating the combustible hazard chemicals. Initially the chlorine-hypochlorite reacts with the combustible hazard chemicals under the activation temperature range to break up the original rigid chemical formulation, once the chemical formulations of combustible hazard chemicals are broken, the remained combustible hazard chemical compounds continue the chain reaction by further reacting with hydrogen and chlorine-hypochlorite to become final basic components.

The advantage of applying ozone and chlorine-hypochlorite in the combustion process is that the attachments of ozone and chlorine-hypochlorite on the combustible hazard chemicals make the combustible hazard chemicals into a reaction ready stage. In the beginning of burning stage, the molecules of combustible hazard chemicals keep absorbing energy and become actively react with ionized molecules such as ozone and chlorine-hypochlorite. When the temperature of combustion chamber increases to a level to start activating, extra ozone and chlorine-hypochlorite attached on the molecule of combustible hazard chemicals can provide electron exchange to form an intermediate chemical, and can improve the break up of the original tightly molecular formulation. The unstable intermediate chemical molecule continues reacting with hydrogen and oxygen to form the final basic products such as hydrogen chloride, water and carbon dioxide, and other final products.

The ability of burning combustible materials as the extra fuel in the electrolytic combustion process is one the major advantages of the energy conversion system 10 to improve the emission of industrial exhaust or biological fermentation exhaust. As discussed previously, the extra fuel from industrial exhaust as carbon monoxide, solid carbon particles and light or heavy weight hydrocarbon materials; the extra fuel from biological fermentation by-products as carbon monoxide, and light weight hydrocarbon materials; the extra fuel from industrial waste such as hydrocarbon chemicals and combustible hazard chemicals; all of the combustible materials listed above can be converted their chemical energy into the power output in the energy conversion system 10 to generate electricity. Due to fast chemical reaction of hydrogen burning, the ratio of the extra fuel to air and the ratio of the extra fuel to hydrogen need to be adjusted for each type of the extra fuel in order to make hydrogen burning and the extra fuel burning compatible in the combustion device 24. It is understood that the molecular size of the extra fuel affects its burning behavior in the combustion process. A light molecular weight fuel material does not need to receive a lot of energy to raise its temperature up to the chemical activation temperature. A heavy molecular weight fuel material requires receiving a lot more energy to raise temperature to its chemical activation temperature.

The energy conversion system 10 of the present invention can be adapted to fit into a vehicle to improve vehicle's fuel efficiency and exhaust emission. A vehicle can be an automobile, a truck, a boat, a moving object, or a flight object. For a vehicle burning gasoline fuel by an internal combustion engine equipped with igniters, the gasoline fuel burning provide the power source to maneuver the vehicle. The internal combustion engine equipped with igniters can be a piston engine, a rotary engine, or an engine with a moving part to provide mechanical output. The vehicle's engine, which is the combustion device 24 of the energy conversion system 10, generates mechanical output to move the vehicle on demand. In addition, the mechanical output is delivered to the generator 26 to generate electricity. Portion of electricity generated is consumed directly by the vehicle for its specific usage, and the remained electricity can be stored through the charger 28 to a battery, which is the energy storage device 12.

Due to limited physical size of battery in the vehicle, when the battery is fully charged, portion of electricity generated from the generator 26 has no immediate usage and needs to be discarded. The energy conversion system 10 adapted into a vehicle can utilize the stored energy from the energy storage device 12 through the wide band frequency converter 14 to the electrolytic cell 20. The hydrogen fuel generated from the electrolytic cell 20 is fed into the combustion device 24 as a supplemental fuel. The energy to perform electrolysis reaction in the electrolytic cell 20 is supplied from the energy storage device 12. The stored energy in the energy storage device 12 is charged by the generator 26 through the charger 28, which is utilized from the extra amount of recoverable energy from the combustion device 24. The water utilized in the electrolytic combustion process is an energy conversion media to perform the energy conversion process. The direct benefit of this energy conversion system 10 in a vehicle is to improve vehicle's fuel efficiency and emission exhaust.

The burning velocity difference between gasoline burning and hydrogen burning is substantial. In order to achieve compatible mixture burning of hydrogen and gasoline in the same combustion chamber, the amount of hydrogen fuel needs to be limited in the fuel mixture. This can avoid pre-ignition of hydrogen burning in the combustion chamber and also can avoid overheating of the combustion chamber. When too much amount of hydrogen mixes with gasoline in the combustion chamber to perform combustion burning process, it requires extra work to perform the up stroke compression cycle. The pre-ignition burning caused by hydrogen can generate knocking on the engine, and inevitably can decrease the mechanical output. The phenomena of miss fire or pre-ignition in the internal combustion engine equipped with igniter actually can reduce the engine performance and also can reduce the vehicle's fuel efficiency. Therefore a proportional valve is needed to properly mix hydrogen and gasoline fuel with air before entering into the combustion chamber. The amount of hydrogen is preferred to be less than 25% of total fuel in the combustion chamber of the internal combustion engine equipped with igniters, and more preferred range of hydrogen is less than 20% of total fuel.

It is understood that there is a fundamental difference for adapting the energy conversion system 10 to consume extra fuel and the adaptation of energy conversion system 10 into a vehicle to burn mixture of hydrogen and gasoline fuel. While the energy conversion system 10 is adapted into a vehicle, which has an internal combustion engine equipped with igniters, the internal combustion engine equipped with igniters is required to produce expected torque under variable speed in order to move vehicle when it is need. Consequently, the pre-ignition caused by hydrogen and the burning velocity difference between hydrogen and gasoline become one of major concern and it is preferred to limit amount of hydrogen in the fuel mixture into the internal combustion engine. While the energy conversion system 10 is adapted to consume extra fuel such as industrial exhaust, biological fermentation exhaust, aromatic chemicals, and other hydrocarbon chemicals, for improving emission or other treatment, the combustion device 24, if an internal combustion engine equipped with igniters is used, does not need to be quick response and generate expected high torque, therefore this restriction of hydrogen percentage in the fuel does not apply. For example, when utilizing the energy conversion system to treating industrial exhaust, the hydrogen can be the majority source of fuel in the whole fuel mixture.

Because a moving vehicle needs mechanical output on demand, the cycle speed of internal engine combustion needs to be increased correspondingly whenever it is instructed. This needs quick response from the electrolytic cell 20 to generate sufficient quantity of hydrogen. The electrolytic cell 20 can have plurality sets of electrode plates. Each set contains anode and cathode plates. A switch connection device (not shown) is electrically connected between the wide band frequency converter 14 and the each set of electrode plates in the electrolytic cell 20. When engine is at idle speed, one set of electrode plates is switched on to receive electric current and to generate hydrogen fuel to sustain engine running. When engine speed is increasing, two or more sets of electrode plates are switched on correspondingly in order to supply more hydrogen fuel to meet the demand. When engine is off or there is no need for hydrogen fuel at a given time, the switch connection device turns off all the electrical connections to the electrolytic cell 20 in order to terminate the hydrogen fuel generation. This control set up can provide the quantity of hydrogen fuel corresponding to engine consumption and can avoid the need to have a storage device to store hydrogen fuel.

Instead of burning the mixture of hydrogen and gasoline in the internal combustion engine equipped with igniters, the vehicle also can operate in the hydrogen mode and the gasoline mode. During the hydrogen mode, hydrogen is the main fuel source to burn in the combustion chamber. The efficient hydrogen burning makes engine cold start easy. A fuel injector device properly mixes hydrogen fuel with air, and delivers to the combustion chamber. The efficiency of generating hydrogen from the electrolytic cell 20 can support vehicle's maneuver ability. The make up water is constantly supplied to replace the water consumption in the electrolytic cell 20. When the electricity at the energy storage device 12 drops to a predetermined value, the vehicle is switching to the gasoline mode. The switch connection device terminates the generation of hydrogen. A second fuel injector device mixes gasoline fuel with proper ratio of air and delivers to the combustion chamber. During the operation of gasoline mode, when the energy in the energy storage device 12 reaches back to a predetermined level, the vehicle is switching back to the hydrogen mode operation.

In addition, a vehicle having an internal combustion engine equipped with igniters can operate in the hydrogen mode and the mixture mode. The hydrogen mode is to operate a vehicle by using hydrogen as the major fuel. The mixture mode is to operate a vehicle by using mixture of hydrogen and gasoline as fuel.

For a vehicle equipped with an internal combustion engine without igniter, which also is known as diesel engine or multi-fuel engine, is designed to burn fuel with relatively large molecular weight. The physical phenomenon of fuel burning in an internal combustion engine equipped with igniters is different compared to the fuel burning in an internal combustion engine without igniter. The internal combustion engine without igniter has relatively high compression ratio. Generally the compression ratio can be 20 or higher. During the up stroke compression cycle, the chamber temperature rises quickly, and when the compression cycle reaches the top end, the chamber temperature becomes high enough to activate fuel burning process. The combustion burning increases the chamber pressure and temperature to push down the piston, and the chamber starts its down stroke cycle. When mixing hydrogen fuel with diesel fuel or other fuel with relative large size molecules, the mixture is initially vaporized in the carburetor, and is sprayed into the combustion chamber. During the up stroke compression cycle, the chamber temperature keeps rising, before reaching the top end of compression cycle, the hydrogen fuel already reaches its activation temperature and is self-ignited. For limited amount of hydrogen presented in the combustion chamber, this actually benefits the whole combustion process.

Before the diesel fuel fully reaching combustion burning in the combustion chamber, there are two approaches to raise the chamber temperature. One approach is by compressing fuel and air mixture in the combustion chamber. This is the basic cycle design of diesel or multi-fuel engines. The second approach is to have limited amount of hydrogen to pre-ignite before finishing the complete up stroke compression cycle. When the fuel mixture contains limited amount of hydrogen during the up stroke compression cycle, the high compression ratio of engine cycle makes the preignition of hydrogen near the complete up stroke compression cycle in the combustion chamber. The burning reaction by hydrogen quickly raises the chamber temperature, so when the compression cycle reaches the top end, the rest of fuel, which is relatively large in molecular weight, has absorbed enough heat and is ready to chemically react and to perform combustion process. Because the fuel already receives enough energy to perform combustion burning, the result is more powerful down stroke, better combustion burning, and improves exhaust emission. The amount of hydrogen is preferred to be less than 20% of total fuel in the combustion chamber of the internal combustion engine without igniter, and more preferred range is less than 15% of total fuel, and further preferred range is less than 12% of total fuel.

### INDUSTRIAL APPALIABILITY

The energy conversion system 10 according to the present invention is adapted to be utilized in a wide variety of industrial and municipal applications wherein it is desired to convert energy from low energy potential into usable work or energy with high energy potential. The energy conversion system 10 is adapted particularly to use water as the energy conversion media through the electrolytic combustion process.

When it is desired to utilize the invention into the electricity power distribution system, the energy conversion system 10 can be constructed at various locations to receive low voltage current from various energy resources such as renewable energy resources, industrial waste heat recovery, industrial exhaust, biological fermentation exhaust and to convert various energy resources into desirable high voltage. This allows the energy conversion system 10 at various locations delivering electricity through the electricity power distribution system. This arrangement can decentralize the electricity power generation and distribution, and can reduce the potential bottleneck in the electricity distribution. Even in certain instance, the electricity power distribution system is jammed or out of service for a specific time period, the stored energy can wait and is ready to convert energy to the desired electricity when there is a need. The decentralization of electricity power generation and distribution can reduce the needs to build centralized power plants, which are pricey and also are very time consuming to construct.

When the energy conversion system 10 is adapted to utilize the industrial or biological fermentation exhaust as the extra fuel for energy conversion. The extra benefit is that the industrial exhaust or biological fermentation exhaust after combustion can have better emission and meet local environmental emission requirements. Consequently, in addition to supply surplus electricity, the energy conversion system 10 becomes an energy self-sustainable system to improve the final emission of industrial exhaust or biological fermentation exhaust.

The energy conversion system 10 with proper set up can be adapted to perform wastewater treatment. A filter device can be installed before wastewater entering into the electrolysis cell 20 for removing solid or other alien materials. When the wastewater is presented in the electrolytic cell 20, the electrolysis reaction can dissociate large organic compounds into more basic form of chemical compounds, and further can generate electrolytic products; in some cases it may also generate ionized electrolytic products, to fed into the combustion device 24. A condenser device can be installed at the exhaust of the combustion device 24 to convert water vapor back to liquid form. When the energy storage device 12 is linked with a source of renewable energy, the energy conversion system 10 becomes an energy self-sufficient system to improve water quality and also may supply surplus electricity. If the wastewater contains ionized metal materials, by periodically reversing the polarity of the cathode and the anode can reduce the scale build up on the electrode plate.

The energy conversion system 10 with proper set up can also be installed to convert salt water into fresh water. Salt water can be sea water or water contains other forms of chemical salt. The salt water initially is pre-filtered to remove solid and other alien materials, and is delivered to the electrolytic cell 20 to perform electrolysis reaction. The generated hydrogen gas is burned in the combustion device 24, and a condenser device is located at the exhaust of the combustion device 24 to condense and collect fresh water. When the concentration of salt in the electrolytic cell 20 becomes high enough before forming solid materials at the bottom, the high concentration salt water is discharged from the electrolytic cell 20 and the electrolytic cell 20 further receives replacement from salt water. The discharged high concentration salt water from the electrolytic cell 20 is collected separately. The heat generated in the combustion device 24 can be utilized to heat the high concentration of salt water mixture, and to form solid salt material.

When the energy conversion system 10 is adapted to improve vehicle's fuel efficiency and emission exhaust, if the vehicle has an internal combustion engine equipped with igniters, furthermore, if the body of vehicle has installed solar photovoltaic cells, the solar radiation can be converted and store in the energy storage device 12. The vehicle can operate in the hydrogen mode, which basically consumes electricity from the energy storage device 12 to generate hydrogen fuel. When energy at the energy storage device 12 is running low, the vehicle can switch to the gasoline mode to charge the energy storage device 12. In the event the vehicle is running out of gasoline fuel, the vehicle still can have maneuver ability by burning hydrogen fuel generated from the electrolytic cell 20 for a period of time.

When the energy conversion system 10 is adapted into a vehicle equipped with a diesel engine or multi-fuel engine, the added hydrogen fuel in the combustion chamber, under high pressure, can be self-ignited and can provide the sufficient heat to reach the activation temperature for diesel fuel. The heating caused by hydrogen burning shrinks the diesel fuel droplet size, and quickly activates the diesel fuel burning process. This preheating in the combustion chamber can greatly improve the diesel fuel combustion operation. The outcome is more powerful down stroke, and more complete burning with less amount of carbon monoxide generated. The less amount of carbon monoxide generated also can prolong the service life of catalyst converter in the exhaust pipe. The energy conversion system 10 also can utilize the ability to generate electrolytic products and ionized electrolytic products to adapt into a vehicle equipped with a diesel engine or multi-fuel engine. The fuel is used in a diesel fuel or multi-fuel engine generally having large molecular structures. The result of hydrogen self-ignition can raise the fuel temperature and the attached ionized electrolytic products can increase the chemical reaction of the fuel.

As will be understood by those skilled in the art, various modifications and alternations of the specific structure described above as constituting the preferred embodiment may be utilized with acceptable results. Those skilled in the art will readily recognize that numerous other modifications and alternations of the specific structure, dimensions, material and components may be made without departing from the spirit and scope of the invention. Accordingly, the above disclosure is not to be considered as limiting and the appended claims are to be interpreted as encompassing the entire scope of the invention.

What is claimed is:

1. An energy conversion system, comprising:
(a) a wide band frequency converter to convert an energy potential into an oscillatory voltage, wherein said oscillatory voltage varies with respect to the wide band frequency of said wide band frequency converter,
(b) an electrolytic cell to produce an electrolytic product, wherein said electrolytic cell receives said oscillatory voltage for generating said electrolytic product, wherein said oscillatory voltage reduces the electrostatic effect of the cathode and the anode of said electrolytic cell on said electrolytic product.

2. An energy conversion system according to claim 1, further comprising a combustion device to consume said electrolytic product for producing work and heat.

3. An energy conversion system according to claim 2, further comprising an energy storage device to provide said energy potential for said wide band frequency converter.

4. An energy conversion system according to claim 3, further comprising a generator to convert said work into energy with equal or higher said energy potential.

5. An energy conversion system according to claim 4, further comprising a charger to deliver portion of energy from said generator into said energy storage device.

6. An energy conversion system according to claim 1, wherein said oscillatory voltage decreases with respect to increasing of said wide band frequency.

7. An energy conversion system according to claim 1, wherein said oscillatory voltage periodically reverses the polarity of said cathode and said anode for reducing scale build up said cathode and said anode.

8. An energy conversion system according to claim 1, wherein said wide band frequency is frequency modulated.

9. An energy conversion system according to claim 1, wherein said wide band frequency is magnitude modulated.

10. An energy conversion system according to claim 1, wherein said wide band frequency is pulse width modulated.

11. An energy conversion system according to claim 1, wherein said oscillatory voltage is a series on and off voltage.

12. An energy conversion system according to claim 1, wherein said wide band frequency has a frequency range, said frequency range is at least 1 KHz and no more than 10 MHz.

13. An energy conversion system according to claim 12, wherein said wide band frequency has a signal cycle range, said signal cycle range is no more than 1000000 signals.

14. A method for providing energy, comprising:
(a) converting an energy potential into an oscillatory voltage with a wide band frequency converter, wherein said oscillatory voltage varies with respect to the wide band frequency of said wide band frequency converter,
(b) generating a combustible product with an electrolytic cell, wherein said electrolytic cell receives said oscillatory voltage from said wide band frequency converter, and
(c) heating a mixture of said combustible product with a combustion device to produce energy.

15. The method according to claim 14, wherein said oscillatory voltage decreases with respect to increasing of said wide band frequency.

16. The method according to claim 14, wherein said oscillatory voltage is frequency modulated.

17. The method according to claim 14, wherein said oscillatory voltage is magnitude modulated.

18. The method according to claim 14, wherein said oscillatory voltage is pulse width modulated.

19. The method according to claim 14, wherein said wide band frequency converter has a frequency range of at least 1 KHz and no more than 10 MHz.

20. The method according to claim 14, wherein said oscillatory voltage periodically reverses the polarity of the cathode and the anode of said electrolytic cell.

21. An energy conversion system, comprising:
(a) an electrolytic cell to generate an ionized electrolytic product and a non-ionized electrolytic product,
(b) a combustion device to chemically react said ionized electrolytic product and said non-ionized electrolytic product.

22. An energy conversion system according to claim 21, wherein said ionized electrolytic product is ozone.

23. An energy conversion system according to claim 21, wherein said ionized electrolytic product is chlorine-hypochlorite.

24. An energy conversion system according to claim 21, wherein said ionized electrolytic product and said non-ionized electrolytic product chemically react with fuel in said combustion device.

25. An energy conversion system according to claim 24, wherein said fuel is a hydrocarbon chemical.

26. An energy conversion system according to claim 21, further comprising a wide band frequency converter to provide an energy potential into said electrolytic cell.

27. An energy conversion system according to claim 26, wherein said energy potential is an oscillatory voltage.

28. An energy conversion system according to claim 27, wherein said oscillatory voltage varies with respect to the wide band frequency.

29. An energy conversion system according to claim 27, wherein said oscillatory voltage periodically reverses the polarity of the cathode and the anode of said electrolytic cell.

30. A method for providing energy, comprising:
(a) generating an ionized electrolytic product and a non-ionized electrolytic product with an electrolytic cell; and
(b) heating a mixture of said ionized electrolytic product and said non-ionized electrolytic product to produce energy.

31. The method according to claim 30, further comprising: converting an energy potential to an oscillatory voltage with a wide band frequency converter into said electrolytic cell.

32. The method according to claim 30, wherein said ionized electrolytic product is ozone.

33. The method according to claim 30, wherein said ionized electrolytic product is chlorine-hypochlorite.

34. The method according to claim 31, wherein said oscillatory voltage has a frequency range of at least 1 KHz and no more than 10 MHz.

35. An energy conversion system, comprising:
(a) an energy storage device to store energy and to provide energy in a form of an energy potential,
(b) a wide band frequency converter to convert said energy potential into an oscillatory voltage, wherein said oscillatory voltage varies with respect to the wide band frequency of said wide band frequency converter,
(c) an electrolytic cell having at least one set of the cathode and the anode, wherein said electrolytic cell generates an ionized electrolytic product and a non-ionized electrolytic product, and
(d) a combustion device to chemically react said ionized electrolytic and said non-ionized electrolytic product to produce energy.

36. An energy conversion system according to claim 35, wherein said ionized electrolytic product is ozone.

37. An energy conversion system according to claim 35, wherein said ionized electrolytic product is chlorine-hypochlorite.

38. An energy conversion system according to claim 35, wherein said oscillatory voltage has a frequency range, wherein said frequency range is no more than 10 MHz.

39. An energy conversion system, comprising:
(a) an energy storage device to store energy and to provide energy in a form of an energy potential,
(b) a wide band frequency converter to convert said energy potential into an oscillatory voltage,
(c) an electrolytic cell to produce an electrolytic product, wherein said electrolytic cell receives said oscillatory voltage for generating said electrolytic product, wherein said oscillatory voltage reduces the electrostatic effect of the cathode and the anode of said electrolytic cell on said electrolytic product,
(d) an internal combustion engine equipped with an igniter to burn mixture of said electrolytic product, air and fuel to generate work for a vehicle, wherein the ratio of the number of molecules of said electrolytic product to the number of molecules of fuel is no more than 25%.

40. An energy conversion system according to claim 39, wherein said oscillatory voltage has a frequency range, wherein said frequency range is no more than 10 MHz.

41. An energy conversion system, comprising:
(a) a switch device to select an operation mode of said energy conversion system, wherein said operation mode has a hydrogen mode and a gasoline mode,
(b) an energy storage device to store energy and to provide energy in a form of an energy potential,
(c) a wide band frequency converter to convert said energy potential into an oscillatory voltage,
(d) an electrolytic cell to produce an electrolytic product, wherein said electrolytic cell receives said oscillatory voltage for generating said electrolytic product, wherein said oscillatory voltage reduces the electrostatic effect of the cathode and the anode of said electrolytic cell on said electrolytic product,
(e) an internal combustion engine equipped with an igniter to generate work, wherein said internal combustion engine burns said electrolytic product mixed with air during said hydrogen mode, and wherein said internal combustion engine burns gaseous gasoline mixed with air during said gasoline mode.

42. An energy conversion system according to claim 41, wherein said oscillatory voltage has a frequency range, said frequency range is no more than 10 MHz.

43. An energy conversion system, comprising:
(a) an energy storage device to store energy and to provide energy in a form of an energy potential,
(b) a wide band frequency converter to convert said energy potential into an oscillatory voltage,
(c) an electrolytic cell to produce electrolytic product, wherein said electrolytic cell receives said oscillatory voltage for generating said electrolytic product, wherein said oscillatory voltage reduces the electrostatic effect of the cathode and the anode of said electrolytic cell on said electrolytic product,
(d) an internal combustion engine burns a mixture of said electrolytic product, air, and fuel by increasing the pressure of said mixture and causing said mixture to self-ignite, wherein the ratio of the number of molecules of said electrolytic product to the number of molecules of said fuel is no more than 20%.

44. An energy conversion system according to claim 43, wherein said oscillatory voltage has a frequency range, said frequency range is no more than 10 MHz.
